(19) United States
(12) Patent Application Publication
(10) Pub. No.: US 2016/0248237 A1
(43) Pub. Date: Aug. 25, 2016

(54) AIR INLET AND AIR OUTLET OPENINGS FOR A VERTICAL BUSBAR SYSTEM, ESPECIALLY FOR WIND POWER PLANTS

(71) Applicant: Siemens Aktiengesellschaft, Muenchen (DE)

(72) Inventors: Frank ALEFELDER, Neunkirchen-Seelscheid (DE); Frank BERTELS, Koeln (DE); Rainer HAAR, Bonn (DE)

(21) Appl. No.: 15/142,164

(22) Filed: Apr. 29, 2016

Related U.S. Application Data
(63) Continuation of application No. 14/391,801, filed on Oct. 10, 2014.

(30) Foreign Application Priority Data
Apr. 13, 2012 (DE) 102012206076.6

(51) Int. Cl. H02G 5/04; H05K 7/20

(52) U.S. Cl. CPC H02G 5/04; H05K 7/20

(57) ABSTRACT

A busbar system is disclosed for the transport of electrical energy, the busbar system being in a vertical setup position. The busbar system includes at least one busbar and a cover surrounding the at least one busbar, the busbar system being divided into elements, each element having an inlet opening in a lower region of the housing and an outlet opening in an upper region of the housing. The housing is substantially closed between the inlet opening and the outlet opening of each element.

### PRIORITY STATEMENT

This patent application is a continuation of and claims priority under 35 U.S.C. §§120/121 to U.S. patent application Ser. No. 14/391,801 filed Aug. Oct. 10, 2014, which is the national phase under 35 U.S.C. §371 of PCT International Application No. PCT/EP2013/053098 which has an International filing date of Feb. 15, 2013, which designated the United States of America, and which claims priority to German patent application number DE 102012206076.6 filed Apr. 13, 2012, the entire contents of each of which are hereby incorporated herein by reference.

### BACKGROUND

Electrical distribution systems can be designed as busbar systems. Busbar systems are used to transport and distribute electrical energy. A busbar system is typically responsible for the connection from a transformer via a main distribution frame to the subsidiary distribution frame, or for the supply to bulk consumers, for example. Busbar systems are likewise used in wind power plants to conduct the current produced by a generator in the head of the tower to the foot of the tower. The busbars of a busbar system are typically housed in a busway section which prevents the occurrence of any undesired electrical contact between busbars and the environment. In this case, the busway section is so dimensioned as to provide the clearances which prevent any undesired electrical contact, and to cool the busbars within the busway section by natural or forced convection.

The housings of conventional busbar systems form a functional unit together with the busbars, thereby placing restrictions on the dimensioning of the busbar elements and on the ventilation of the system. When transporting energy over long vertical distances in particular, e.g. in high-rise buildings or in wind power plants, the limited ventilation and/or convection within the busway sections result in an accumulation of heat in the upper region of the installed busbar systems.

10 2012 202 435 DE proposes a busbar system which can comprise a plurality of busbars of different types. For example, the busbar system disclosed in 10 2012 202 435 DE may be composed of two busbar types having different cross-sectional areas and a different number of busbars of the individual types.

In the case of conventional busbar systems ventilated by air, the clamping point in a vertical setup position forms a barrier and thus creates a narrowed cross section A_{clamp} which obstructs the draft that has been warmed in free convection and flows vertically upwards. Owing to the reduced suction effect, only a very modest airflow speed v_{L} is achieved and therefore only a relatively small mass flow \dot{m}_{L} flows through the channel. Owing to the modest mass flow, only a small amount of heat Q can be absorbed by the airflow and carried away. There is a danger that the channel will overheat or that the heat will transfer to the periphery (e.g. housing or cover) and cause the permitted limit values for the heat to be exceeded there.

\dot{V}_{L}=A_{clamp}·v_{L}

\dot{m}_{L}=\dot{V}_{L}·ρ_{L}=A_{clamp}·v_{L}·ρ_{L}

\dot{Q}=c_{L}·\dot{m}_{L}·(Θ_{air,max}−Θ_{air,environment})

### SUMMARY

An embodiment of the invention provides a busbar system in which there is no accumulation of heat.

The busbar system of an embodiment for transporting electrical energy is in a vertical setup position, said busbar system comprising at least one busbar and a cover which surrounds the at least one busbar, wherein the busbar system is divided into elements, each element having an inlet opening in a lower region of the cover and an outlet opening in an upper region of the cover, and wherein the cover is substantially closed between the inlet opening and the outlet opening of each element.

In one embodiment, the busbar system is divided into at least two elements.

In a further embodiment, the busbar system has at least two elements of different length.

In one embodiment, the area of the inlet opening is larger than the area of the outlet opening of each element. In particular, the area of the inlet opening can be so designed as to be 10% larger than the area of the outlet opening of each element.

In a further embodiment, the at least one busbar is composed of segments which are interconnected via a coupling point.

In one embodiment, the coupling points of the busbar segments are situated outside of the elements.

In a further embodiment, the coupling points are surrounded by a cover which is substantially closed.

In one embodiment, the busbar system for transporting electrical energy comprises at least one first segment and one second segment, the segments each comprising at least one first busbar having a first cross-sectional area, at least one second busbar having a second cross-sectional area, a retaining unit and at least one connection, wherein the busbars of the segments are retained by the respective retaining units and electrically interconnected via the at least one connection.

It is advantageous here that the size of the busbars can be adapted as required, since their dimensioning is not limited by a system housing. Likewise, a better thermal lift can be generated in the housing as a result of increasing the clearances of busbars from a potential housing. By virtue of this effect, the heat dissipation improves and the current carrying capacity of the busbars is increased.

In one embodiment, the busbars of the segments are so designed as to extend in the direction of the current flow.

In a further embodiment, the segments comprise a plurality of first busbars and/or a plurality of second busbars, said busbars being so arranged as to be parallel with each other in the respective segment.

In one embodiment, the retaining units comprise a first bolt-type connection, wherein the first busbars of the respective segments are electrically interconnected in that the ends of the first busbars lie flat against each other and the first bolt-type connection exerts a force which presses the ends of the first busbars together, said ends lying flat against each other.

In a further embodiment, the retaining units comprise a second bolt-type connection, wherein the second busbars of the respective segments are electrically interconnected in that the ends of the second busbars lie flat against each other and the second bolt-type connection exerts a force which presses the ends of the second busbars together, said ends lying flat against each other.

The retaining units of the segments can be used as retaining device(s) for fastening the busbar system.

In one embodiment, the first cross-sectional area of the first busbars differs from the second cross-sectional area of the second busbars. The first cross-sectional area of the first busbars may differ from the second cross-sectional area of the second busbars because the height of the first busbars differs from that of the second busbars.

### BRIEF DESCRIPTION OF THE DRAWINGS

The invention is described below with reference to the following embodiments and figures, in which:

FIG. 1A shows a busbar system comprising a first segment and a second segment illustrated in a first projection,

FIG. 1B shows a segment of a busbar system with first busbars and second busbars illustrated in a second projection,

FIG. 2A shows a busbar system comprising a first segment and a second segment with a cover,

FIG. 2B shows a detailed view of a retaining unit with a first and a second bolt-type connection,

FIG. 3 shows a busbar system comprising a first and a second segment illustrated in a third projection,

FIG. 4 shows an adapter for a busbar system,

FIG. 5 shows a top view of the tower of a wind power plant with busbar system, and

FIG. 6 shows a busbar system with elements.

### DETAILED DESCRIPTION OF THE EXAMPLE EMBODIMENTS

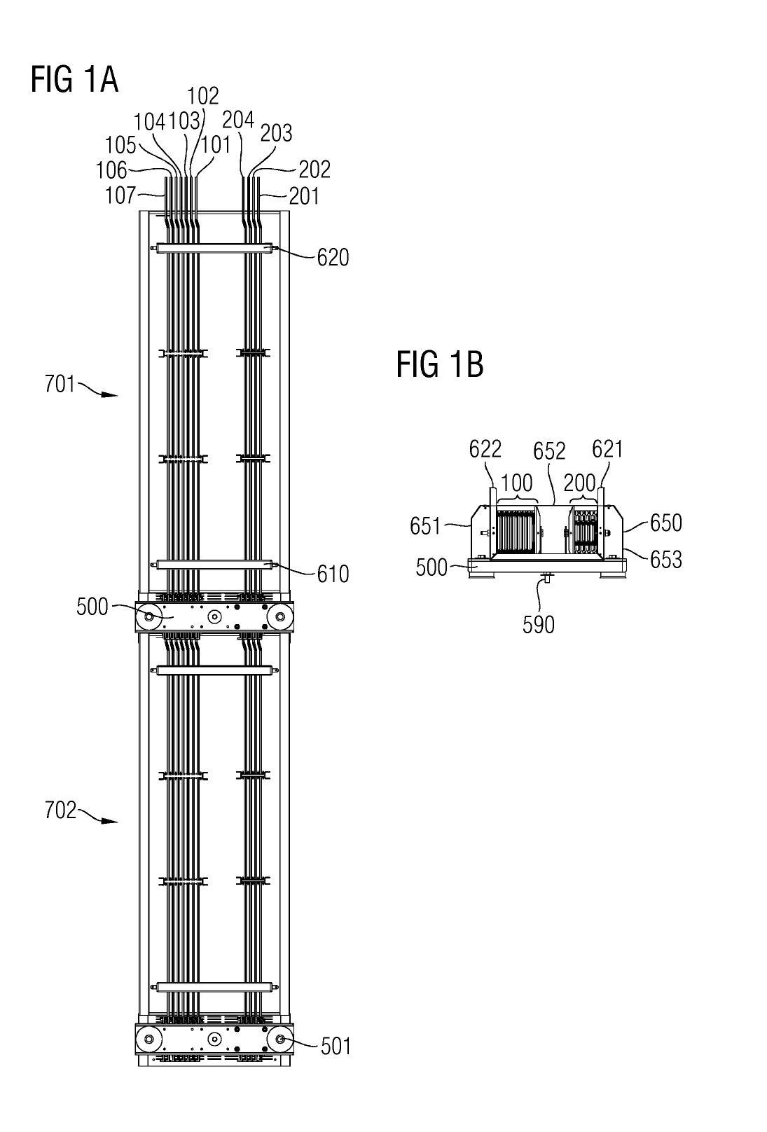

FIG. 1A shows a busbar system for transporting electrical energy, illustrated in a first projection of the top view of the busbar system. The busbar system comprises a first segment 701 and a second segment 702. The segments 701, 702 each comprise first busbars 101, 102, 103, 104, 105, 106, 107 having a first cross-sectional area and a retaining unit 500, 501, the busbars of the respective segments 701, 702 being retained by the respective retaining units 500, 501 and electrically interconnected via a connection 510, 520. According to FIG. 1A, the retaining unit 500 is assigned to the first segment 701 and retaining unit 501 to the second segment 702. The connection 510, 520 connects the respective first busbars 101, 102, 103, 104, 105, 106, 107 of the first and second segments.

The busbars of the busbar system according to an embodiment of the invention are so designed as to extend in the direction of the current flow. According to the illustration in FIG. 1A, this means that the current flow runs vertically and therefore the busbars are likewise so configured as to extend vertically. The individual first busbars 101, 102, 103, 104 of the respective segments 701, 702 are so arranged as to be parallel with each other.

FIG. 1B shows the busbar system according to an embodiment of the invention, illustrated in a second projection. In comparison with FIG. 1A, the illustration in FIG. 1B is perpendicular relative to the current flow. The retaining unit 500 retains the first busbars 100 and also has a fastening device 590 which is used as a retaining device for fastening the busbar system. The fastening device 590 may take the form of a screw, for example, such that the segments can be fastened to a wall or a support by way of the screws 590.

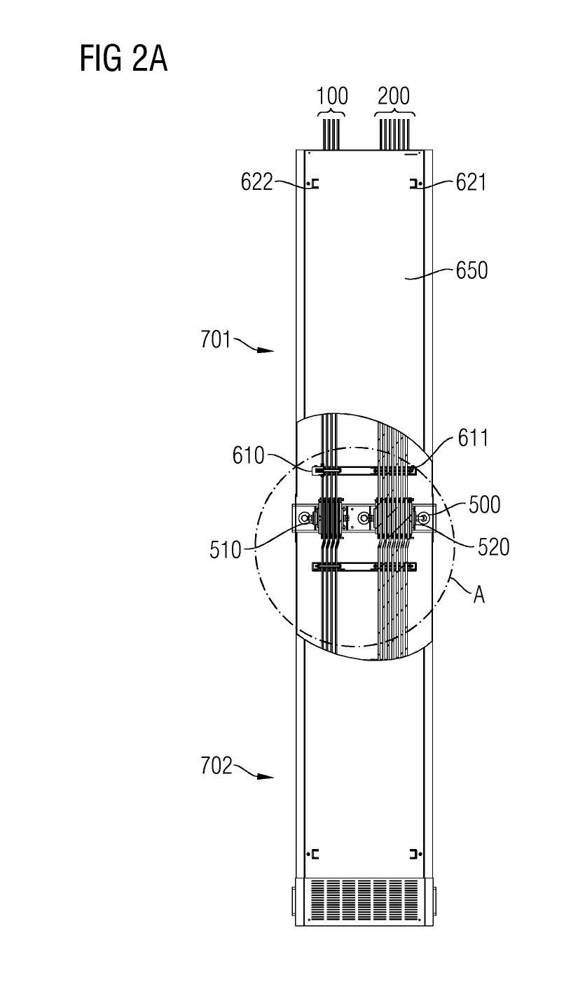

As shown in FIG. 1A, the segment 710 also has retainers 610, 620 which are attached directly to the busbars. A cover 650 may be fastened to the retainers 610, 620 as illustrated in FIG. 2A. The retainers 610, 620 may have arms 621, 622, which extend perpendicularly relative to the alignment of the busbars and which support the cover 650. In this case, the arms 621, 622 of the retainers 610, 620 can reach through openings in the cover 650 and fix the latter thereby. In order to prevent the cover 650 from coming loose, it may be fixed by way of screws, rivets or other fastening device after the cover 650 has been placed on the busbar system.

The retaining unit 500 is illustrated in greater detail in FIG. 2B. The retaining unit 500 connects the first segment 701 to the second segment 702. The first segment 701 comprises first busbars 101, 102, 103, 104. The second segment 702 comprises first busbars 101′, 102′, 103′, 104′. The first busbars of the segments 701, 702 are electrically interconnected in that the ends of the first busbars lie flat against each other and a first bolt-type connection 510 exerts a force which presses the ends of the first busbars together, said ends lying flat against each other. The ends of the first busbars of the respective segments 701, 702 may be designed in the form of a hook on one side and feature a hole on the other side, through which the bolt-type connection of the retaining unit 500, 501 passes. This choice of structure for the ends of the first busbars allows the segments 701, 702 to be assembled with particular ease. After assembly of the retaining units 500, 501, the hooks can be swiveled into the bolt-type connection and the bolt-type connection tightened.

The first segment 701 also comprises second busbars 201, 202, 203, 204, 205, 206, 207 having a second cross-sectional area, which may differ from the first cross-sectional area of the first busbars 101, 102, 103, 104. FIG. 1B illustrates the different cross-sectional areas of the first busbars 100 and second busbars 200. The second busbars likewise run parallel with each other in the respective segments 701, 702. According to the FIGS. 1A, 2A and 2B, the first busbars 101, 102, 103, 104 and the second busbars 201, 202, 203, 204, 205, 206, 207 run parallel with each other.

The first cross-sectional area of the first busbars 101, 102, 103, 104 differs from the second cross-sectional area of the second busbars 201, 202, 203, 204, 205, 206, 207 because the height of the first busbars 101, 102, 103, 104 differs from that of the second busbars 201, 202, 203, 204, 205, 206, 207.

According to FIG. 2B, the retaining unit 500 comprises a second bolt-type connection 520. The second busbars 201, 202, 203, 204, 205, 206, 207 of the first segment 701 are electrically connected to the second busbars 201′, 202′, 203′, 204′, 205′, 206′, 207′ of the second segment 702 by way of said second bolt-type connection 520, in that the ends of the second busbars lie flat against each other and a second bolt-type connection 520 exerts a force which presses the ends of the second busbars together, said ends lying flat against each other.

According to the example embodiment illustrated here, the retaining units 500, 501 include the connections 510, 520. However, it is equally conceivable for the connections 510, 520 which electrically interconnect the respective busbars of the segments 701, 702 to be separate from the retaining units 500, 501. Consequently, the retaining units 500, 501 could be physically arranged at the centers of the busbars while the connections 510, 520 are situated at the ends of the busbars.

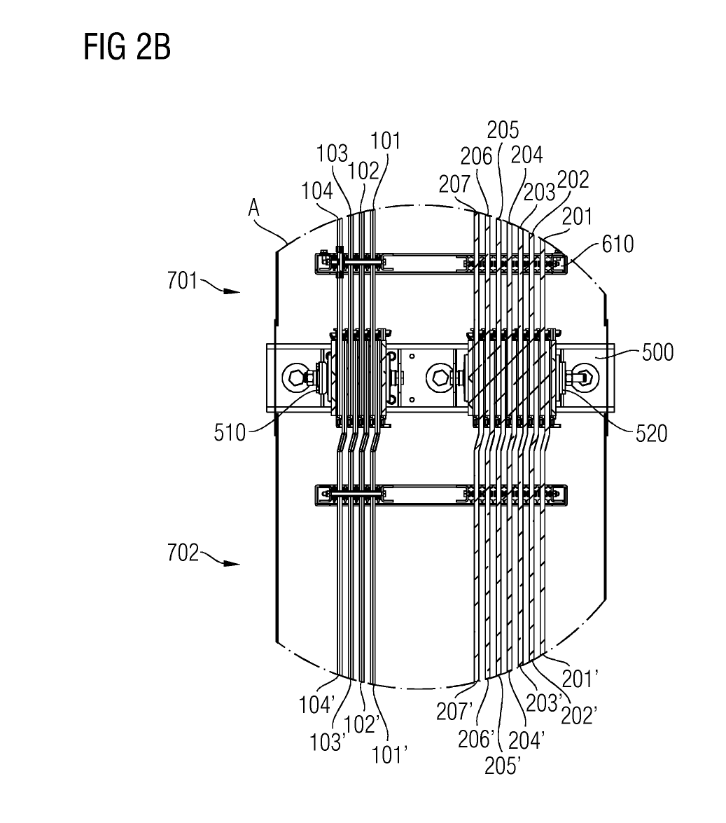

FIG. 3 illustrates the busbar system according to an embodiment of the invention in a third projection. The illustration is a lateral view of the busbar system according to FIG. 1A rotated by an angle of 90°. The busbar system comprises the first segment 701 and the second segment 702. The busbars of the segments are electrically interconnected via the connection 510, 520 of the retaining unit 500. The retaining unit 500 comprises a retaining device 590 for fastening the busbar system. For example, the busbar system can be screwed to a wall 800 via the retaining device 590. The busbar system comprises retainers 610, 620 with arms 611, 621 onto which a cover 650 can be pushed and then fixed.

The cover 650 may be so designed as to attach only to those sides of the segments 701, 702 which face away from the fastening of the busbar system. According to FIG. 3, this means that the cover is not situated on the underside, which faces the wall 800, but runs only along the sides of the busbars and above the busbars parallel with the wall 800. According to FIG. 1B, this means that the cover 650 includes three segments, specifically the segments 653 and 651 running approximately parallel with the busbars 100, 200 and the segment 652 running approximately parallel with a wall 800.

The first busbars 100 and second busbars 200 of the respective segments 701, 702 can likewise be interconnected via a single bolt-type connection.

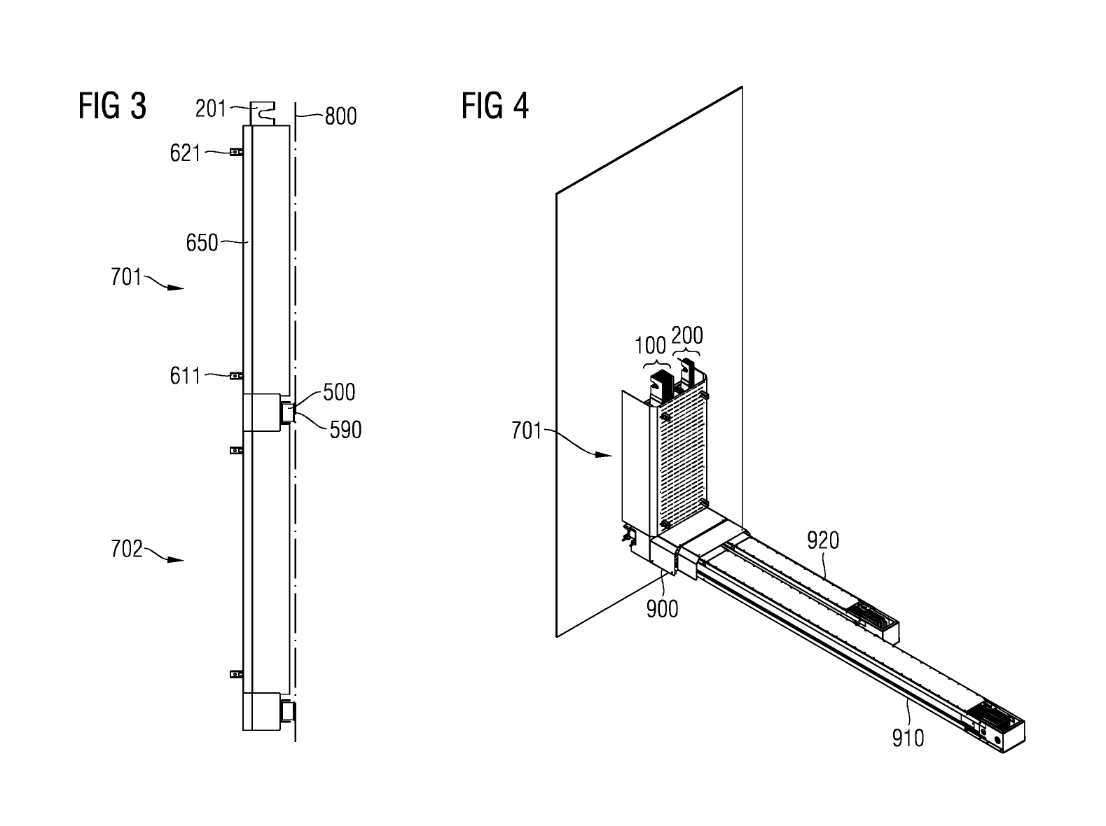

FIG. 4 illustrates an adapter 900, which connects the busbar system according to an embodiment of the invention to conventional busbar systems. The busbar system according to an embodiment of the invention comprises first busbars 100 and second busbars 200, both of which are electrically connected to the adapter 900. Bolt-type connections can again be used as a connection. The adapter 900 likewise also has connection interfaces for a first external busbar system 910. The first external busbar system 910 has the same number of busbars as the number of first busbars of the busbar system according to an embodiment of the invention, said busbars having the same cross-sectional areas. The adapter 900 likewise connects the second busbars of the busbar system according to an embodiment of the invention to a second external busbar system 920. The second external busbar system 920 is a busbar system which has the same number of busbars as the number of second busbars of the busbar system according to an embodiment of the invention. The cross-sectional areas of the second busbars of the busbar system according to an embodiment of the invention are likewise identical to those of the busbars of the second external busbar system.

The adapter 900 can be so designed as to allow a right-angled connection interface between the busbar system according to an embodiment of the invention and the first and second external busbar systems.

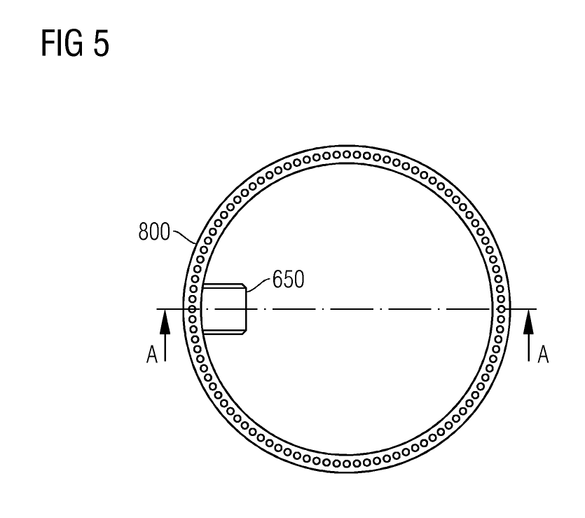

FIG. 5 illustrates a top view of the tower of a wind power plant comprising a busbar system. A busbar system with a cover 650 is attached to the tower wall 800.

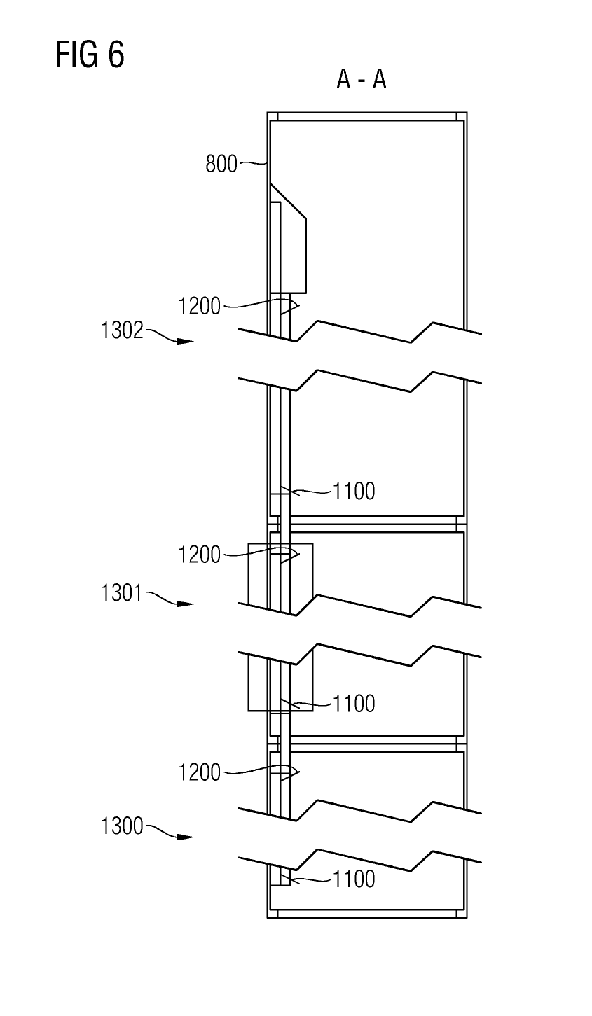

FIG. 6 illustrates the tower 800 of a wind power plant in a vertical setup position. The busbar system is installed inside the tower 800. The busbar system includes three elements 1300, 1301 and 1302. Each element 1300, 1301, 1302 is provided with an inlet opening 1100 in the lower region of the cover 650 of the element 1300, 1301, 1302, and an outlet opening 1200 in the upper region of the cover 650 of the element 1300, 1301, 1302. The cover 650 is substantially closed between the inlet opening 1100 and the outlet opening 1200.

The elements 1300, 1301, 1302 may differ in length. The elements 1300, 1301, 1302 may be formed by the segments 701, 702 of the busbar system. The coupling points, e.g. the first bolt-type connection 510 or the second bolt-type connection 520, are then situated outside of the respective element. It is also conceivable for a plurality of segments of the busbar system to be situated within an element.

The busbar channel is so configured in its dimensions as to prevent an accumulation of heat in the region of the coupling. The busbar channel is divided by the elements into flow sections, each of which is provided with an inlet opening 1100 at the beginning (bottom) and an outlet opening 1200 at the end (top). The area of the inlet opening 1100 may be designed to be 10% larger than the area of the outlet opening 1200, thereby boosting the chimney effect. Due to the absorption of the busbar heat and the resulting change in volume of the air, a vertical upward flow is generated which can absorb and hence carry away more heat energy in the consequently increased mass flow, without thereby exceeding the permitted housing temperature.

The cross section of the cover 650 should be so designed as to be significantly larger than the cross section of the busbars.

The inlet opening 1100 and the outlet opening 1200 may be configured such that the respective protection type of the overall system is preserved. With regard to flow, the inlet opening 1100 and the outlet opening 1200 are so configured as to ensure an optimal inflow and outflow of the air.

The inlet opening 1100 is configured such that air from below (cold air) can be sucked in. The outlet opening 1200 is configured such that air can flow upwards (hot air) and out in an unobstructed manner and dissipate into the environment.

The cover 650 and the busbars are no longer considered as unitary but as separate elements in the busbar system according to the invention, thereby providing inter alia advantages as follows. The size of the busbars can be adapted as required, since their dimensioning is not limited by a system housing. Likewise, the number of busbars and the cross-sectional area of the busbars are variable and can be selected to suit the individual application. For example, a housing may contain a busbar system comprising four first busbars and seven second busbars. By increasing the clearances of busbars from the cover, it is possible to generate a better thermal lift in the cover (chimney effect). By virtue of this effect, the heat dissipation improves and the current carrying capacity of the busbars is increased. An additional cost benefit is achieved by combining a plurality of busbars having different cross-sectional areas under one cover.

1.-15. (canceled)

16. A busbar system for transporting electrical energy, wherein the busbar system is situated in a vertical setup position, the busbar system comprising:
at least one busbar designed to extend in the direction of vertical current flow; the at least one busbar is composed of segments; the segments are interconnected by coupling points;
a cover which surrounds the at least one busbar;
a busbar channel formed by the cover;
elements by which the busbar channel is divided into flow sections, wherein coupling points of the busbar segments are situated outside and between the respective elements; the coupling points are also surrounded by the cover which is substantially closed, so that the coupling points in a vertical setup position creating a narrowed cross section and forming a barrier; wherein each of the elements includes an inlet opening in a relatively lower region of the cover and an outlet opening in a relatively upper region of the cover, and wherein the cover is substantially closed between the inlet opening and the outlet opening of each of the elements.

17. The busbar system of claim 16, wherein the at least two elements include different lengths.

18. The busbar system of claim 16, wherein an area of the inlet opening is relatively larger than the area of the outlet opening of each element.

19. The busbar system of claim 16, wherein the busbar system further comprises at least one first segment and one second segment, wherein the first and second segments each comprise at least one first busbar including a first cross-sectional area, at least one second busbar including a second cross-sectional area, a retaining unit and at least one connection, wherein the busbars of the first and second segments are retained by the respective retaining units and are electrically interconnected via the at least one connection.

20. The busbar system of claim 19, wherein the busbars of the first and second segments are designed to extend in a direction of the current flow.

21. The busbar system of claim 19, wherein the first and second segments comprise at least one of a plurality of first busbars and a plurality of secondbusbars, arranged be parallel with each other in the respective segment.

22. The busbar system of claim 19, wherein the retaining units comprise a first bolt-type connection, and wherein the first busbars of the respective segments are electrically interconnected in that the ends of the first busbars lie flat against each other and the first bolt-type connection exerts a force which presses the ends of the first busbars together, said ends lying flat against each other.

23. The busbar system of claim 19, wherein the retaining units comprise a second bolt-type connection, and wherein the second busbars of the respective segments are electrically interconnected in that the ends of the second busbars lie flat against each other and the second bolt-type connection exerts a force which presses the ends of the second busbars together, said ends lying flat against each other.

24. The busbar system of claim 19, wherein the retaining units of the segments are used as retaining at least one device for fastening the busbar system.

25. The busbar system of claim 16, wherein the first cross-sectional area of the first busbars differs from the second cross-sectional area of the second busbars.

26. The busbar system of claim 25, wherein the first cross-sectional area of the first busbars differs from the second cross-sectional area of the second busbars because the height of the first busbars differs from that of the second busbars.

27. The busbar system of claim 16, wherein the area of the inlet opening is relatively larger than the area of the outlet opening of each elements.

28. The busbar system of claim 18, wherein the area of the inlet opening is 10% larger than the area of the outlet opening of each element.

29. The busbar system of claim 27, wherein the area of the inlet opening is 10% larger than the area of the outlet opening of each element.

30. The busbar system of claim 20, wherein the first and second segments comprise at least one of a plurality of first busbars and a plurality of second busbars, arranged be parallel with each other in the respective segment.
